(19) United States
(12) Patent Application Publication
(10) Pub. No.: US 2026/0363093 A1
(43) Pub. Date: Nov. 12, 2026

(54) REDUCING BONDING TEMPERATURE OF METAL

(71) Applicant: International Business Machines Corporation, Armonk, NY (US)

(72) Inventors: Kevin Wayne Brew, Niskayuna, NY (US); Ching-Tzu Chen, Ossining, NY (US); Timothy Mathew Philicelli, Albany, NY (US); JIN PING HAN, Yorktown Heights, NY (US); Nicholas Alexander POLOMOFF, Hopewell Junction, NY (US); Yasir Sulehria, Niskayuna, NY (US); Christopher M Bottoms, Albany, NY (US)

(21) Appl. No.: 19/203,137

(22) Filed: May 8, 2025

(51) Int. Cl. H10W 70/05; H10W 70/65; H10W 70/66; H10W 72/00; H10W 72/90; H10W 80/00; H10W 90/00

(52) U.S. Cl. CPC H10W 70/05; H10W 70/65; H10W 70/66; H10W 72/01921; H10W 72/01953; H10W 72/01961; H10W 72/923; H10W 72/926; H10W 72/9415; H10W 80/312; H10W 80/327; H10W 90/792; H10W 90/794

(57) ABSTRACT

A semiconductor structure includes a first dielectric material layer, a first metal wiring embedded in the first dielectric material layer, a second dielectric material layer, a second metal wiring embedded in the second dielectric material layer, and a first dopant material in the first metal wiring. The first dielectric material layer is bonded to the second dielectric material layer and the first metal wiring is bonded to the second metal wiring.

### BACKGROUND

The present invention relates to the electrical, electronic, and computer arts, and more specifically, to reducing the temperature at which metals can be bonded within a semiconductor structure.

Semiconductor structures can include integrated circuits (ICs), dies, chips, and the like, which are often mounted or stacked on one or more electrical or electronic structures. For example, an IC, die, chip, etc., or a portion thereof, can be mounted to a carrier, an interposer, other ICs, dies, chips, etc., or a portion thereof, to name a few. That is, a conductive interface of a first sub-structure (e.g., IC, die, chip, etc.) can be directly mechanically and electrically bonded to a conductive interface of a second sub-structure (e.g., a carrier, an interposer, an IC, die, chip, etc.). Advantageously, through such bonding, logic, control, memory, accelerators, sensors, etc., can be combined into one concise 3D package. In some cases, the first sub-structure can be directly bonded (e.g., hybrid bonded) to the second sub-structure to form the semiconductor structure without the use of adhesives.

Such direct bonding of conductive interfaces in semiconductor structures has many advantages. For example, multiple devices (logic, control, memory, accelerators, sensors, etc.) can be stacked such that when incorporated into other circuitry, such as on a printed circuit board (PCB), minimal real estate can be utilized. Further, the minimal distance between the multiple devices can facilitate high-speed operation by providing a close interconnection between the multiple devices.

However, bonding of conductive interfaces and non-conductive interfaces (e.g., such as in hybrid bonding scenarios) can include challenges. To achieve a reliable bond, the amount of heat utilized in the direct bonding of conductive interfaces can be substantial. However, such bonding processes typically occur toward the end of the manufacturing process of the semiconductor structure where certain materials, components, temporary bonds, etc. can be sensitive to excessive heat and, as such, low temperature processes can be advantageous.

### BRIEF SUMMARY

Principles of the invention provide techniques for reducing bonding temperature of metal. In one aspect, an exemplary semiconductor structure includes a first dielectric material layer, a first metal wiring embedded in the first dielectric material layer, a second dielectric material layer, a second metal wiring embedded in the second dielectric material layer, and a first dopant material in the first metal wiring. The first dielectric material layer is bonded to the second dielectric material layer and the first metal wiring is bonded to the second metal wiring.

In another aspect, an exemplary semiconductor structure includes a first sub-structure having a first dielectric material layer and a first metal wiring embedded in the first dielectric material layer, a second sub-structure having a second dielectric material layer and a second metal wiring embedded in the second dielectric material layer, and a first dopant material in the first dielectric material layer and in the first metal wiring of the first sub-structure. The first sub-structure and the second sub-structure are bonded together at the first dielectric material layer of the first sub-structure and the second dielectric material layer of the second sub-structure and at the first metal wiring of the first sub-structure and the second metal wiring of the second sub-structure.

Another aspect provides a method of forming a semiconductor structure including ion implanting a dopant material in at least one of a first dielectric material layer of a first sub-structure and a second dielectric material layer of a second sub-structure; amorphizing, at least in part, at least one of a first metal wiring embedded in the first dielectric material layer of the first sub-structure by ion implanting the dopant material in a first interface of the first metal wiring, and a second metal wiring embedded in the second dielectric material layer of the second sub-structure by ion implanting the dopant material in a second interface of the second metal wiring; bonding the first dielectric material layer of the first sub-structure to the second dielectric material layer of a second sub-structure; and bonding the first interface of the first metal wiring of the first sub-structure to the second interface of the second metal wiring of the second sub-structure.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action other than by performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1A-1C illustrate a method of making sub-structures of a semiconductor structure, according to exemplary embodiments.

FIGS. 2A-2B illustrate a method of ion-implanting sub-structures of a semiconductor structure, according to exemplary embodiments.

FIGS. 3A-3B illustrate a method of ion-implanting sub-structures of a semiconductor structure, according to exemplary embodiments.

FIG. 4 illustrates an example of exemplary sub-structures of a semiconductor structure, according to exemplary embodiments.

FIG. 5 illustrates an example of bonded sub-structures of a semiconductor structure, according to exemplary embodiments.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein (reference characters refer to the drawings discussed below), it will be appreciated that in one aspect, an exemplary semiconductor structure 1000 includes a first dielectric material layer 1005, a first metal wiring 1009 embedded in the first dielectric material layer 1005, a second dielectric material layer 1015, a second metal wiring 1019 embedded in the second dielectric material layer 1015, and a first dopant material 2025a in the first metal wiring 1009. The first dielectric material layer 1005 is bonded to the second dielectric material layer 1015 and the first metal wiring 1009 is bonded to the second metal wiring 1019. Technical benefits include the first dopant material 2025a amorphizing the first metal wiring 1009 at the time of implanting of the first dopant material 2025a, creating a reduced size of grains in the metal of the first metal wiring 1009 prior to a bonding process. An amorphized first metal wiring 1009 with smaller metal grains can increase the probability and strength of a bond between an amorphized first interface 2011 of the first metal wiring 1009 and a second interface 1021 of the second metal wiring 1019. Improvements in the bond between the first metal wiring 1009 and the second metal wiring 1019 can mitigate mechanical stresses at the bond encountered during wafer dicing, singulation, or other operations of the manufacturing process of the semiconductor structure 1000. In turn, potentially reducing occurrences of opens or weakened electrical connections between the bonded first metal wiring 1009 and second metal wiring 1019. Further, technical benefits can include a reduction in a temperature at which the bonding can occur, for example, achieving a bonding temperature below 350 °C. Reduced temperature bonding can mitigate damage to neighboring heat sensitive circuitry.

Optionally, the semiconductor structure 1001 can further include the first dopant material 2025a in the first dielectric material layer 1005. Technical benefits of the first dopant material 2025a being implanted in the first dielectric material layer 1005 include creation of a lower dielectric constant (k) of the first dielectric material layer 1005, reducing a possibility of parasitic coupling between the first metal wire 1009 and the second metal wire 1019.

Further, optionally, the first metal wiring 1009 can have a same width as the second metal wiring 1019 and the first metal wiring 1009 can be fully aligned with the second metal wiring 1019. Thus, optionally, a metal-to-metal bond can be formed. In other options, the first dielectric material layer 1005 can be overlapped and bonded to, at least in part, the second metal wiring 1019, the second dielectric material layer 1015 can be overlapped and bonded to, at least in part, the first metal wiring 1009, or both. Thus, optionally, a metal-to-dielectric bond can be formed. Technical benefits include both the ability to bond metal-to-metal connections when both metal wirings fully align and the ability to bond metal-to-dielectric when both metal wirings do not fully align increasing a probability and strength of a bond between metals and/or a metal and a dielectric, mitigating mechanical stresses at the bond, improving yield, and reducing a bonding temperature for a variety of applications.

Optionally, the first dopant material 2025 a can have a concentration of less than 5 atomic percentage of an implanted volume. In further options, the first dopant material 2025a can be selected from a group including fluorine (F), chorine (Cl), and manganese (Mn). Technical benefits include that by ion implanting an atomic or ionic species, such as fluorine (F), chlorine (Cl), or manganese (Mn) onto at least one of the two metal interfaces, amorphizing, at least in part, the interface, can reduce the size of the grains of the metal (e.g., copper (Cu)) prior to bonding. An amorphized metal wiring with smaller metal grains can increase the probability and strength of a bond, improving the bond between the first metal wiring 1009 and the second metal wiring 1019, mitigating mechanical stresses encountered during manufacturing processes of the semiconductor structure 1000, thus, potentially reducing occurrences of opens or weakened electrical connections in the bond and reducing a temperature at which bonding can occur, mitigating damage to neighboring heat sensitive circuitry.

Optionally, the semiconductor structure 1000 can include a second dopant material 2025b in the second metal wiring 1019. Technical benefits include amorphizing of the second metal wiring 1019 by implanting the second dopant material 2025b, creating a reduced size of grains in the metal of the second metal wiring 1019 prior to bonding. An amorphized first metal wiring 1009 and second metal wiring 1019, reducing the metal grain size in both the first metal wiring 1009 and the second metal wiring 1019, can further increase the probability and strength of a bond between an amorphized first interface 2011 of the first metal wiring 1009 and an amorphized second interface 2021 of the second metal wiring 1019. Accordingly, mechanical stresses at the bond encountered during wafer dicing, singulation, or other operations of the manufacturing process of the semiconductor structure 1000, can be further mitigated, potentially further reducing occurrences of opens or weakened electrical connections between the bonded first metal wiring 1009 and second metal wiring 1019. Further, technical benefits can include a reduction in a temperature at which bonding can occur, potentially mitigating damage to neighboring heat sensitive circuitries.

Continuing with options, the second dopant material 2025b can include a same material as the first dopant material 2025a. Technical benefits include a more simplistic, streamlined process in which the same dopant material 2025a, 2025b can be used for both the first dielectric material layer 1005, the first metal wiring 1009, the second dielectric material layer 1015, and the second metal wiring 1019.

In other options, the second dopant material 2025b can include a different material than the first dopant material 2025a, the second dopant material 2025b can have a concentration of less than 5 atomic percentage of an implanted volume, and the second dopant material can be selected from the group consisting of fluorine (F), chlorine (Cl), and manganese (Mn). Technical benefits include a more versatile process in which dielectric material layers and metal wirings that include differing dopant materials 2025a, 2025b can be bonded together.

In other options, the semiconductor structure 1000 can include a first dielectric cap 1027 on the first dielectric material layer 1005, in which the first dopant material 2025a can be in the first dielectric cap 1027 and the first dielectric material layer 1005 can be bonded to the second dielectric material layer 1015 at an interface between the first dielectric cap 1027 located on the first dielectric material layer 1005 and the second dielectric material layer 1015. Technical benefits include mitigation of diffusion of the first metal wiring 1009 to reduce the potential for leakage and to potentially extend a life of the bond. Further, the first dielectric cap 1027 can potentially reduce an occurrence of voids formed due to metal migration and volume shrinkage after bonding. Still, further, implanting the second dopant material 2025b in the first dielectric cap 1027 located on the first dielectric material layer 1005 can create a lower dielectric constant (k) reducing a possibility of parasitic coupling between the first metal wire 1009 and the second metal wire 1019.

Optionally, the semiconductor structure 1000 can include a second dopant material 2025b in the second dielectric material layer 1015 and the second metal wiring 1019. Technical benefits include amorphizing the second metal wiring 1019 by implanting the second dopant material 2025b, creating a reduced size of grains in the metal of the second metal wiring 1019 prior to bonding. Reducing the metal grain size in both the first metal wiring 1009 and the second metal wiring 1019 can further increase the probability and strength of a bond between an amorphized first interface 2011 of the first metal wiring 1009 and an amorphized second interface 2021 of the second metal wiring 1019. Accordingly, mechanical stresses at the bond encountered during wafer dicing, singulation, or other operations of the manufacturing process of the semiconductor structure 1000, can be further mitigated, potentially further reducing occurrences of opens or weakened electrical connections between the bonded first metal wiring 1009 and second metal wiring 1019. Additionally, due to the smaller grains in both the first metal wiring 1009 and the second metal wiring 1019, a reduction in a temperature at which bonding can occur, potentially further mitigating damage to neighboring heat sensitive circuitries, can be achieved. Further, the first dopant material 2025a implanted in the second dielectric material layer 1015 can create a lower dielectric constant (k) of the second dielectric material layer 1015 reducing a possibility of parasitic coupling between the first metal wiring 1009 and the second metal wiring 1019.

In further options, the semiconductor structure 1000 can include a second dielectric cap 1029 on the second dielectric material layer 1015, in which the first dielectric material layer 1005 can be bonded to the second dielectric material layer 1015 at an interface between the first dielectric material layer 1005 and the second dielectric cap 1029 located on the second dielectric material layer 1015. Technical benefits include mitigation of diffusion of the second metal wiring 1019 to reduce the potential for leakage and to potentially extend a life of the bond. Further, the second dielectric cap 1029 can potentially reduce an occurrence of voids formed due to metal migration and volume shrinkage after bonding.

In still further options, the semiconductor structure 1000 can include a first dielectric cap 1027 on the first dielectric material layer 1005, and a second dielectric cap 1029 on the second dielectric material layer 1015, in which the first dopant material 2025a can be in the first dielectric cap 1027 and the first dielectric material layer 1005 can be bonded to the second dielectric material layer 1015 at an interface between the first dielectric cap 1027 located on the first dielectric material layer 1005 and the second dielectric cap 1029 located on the second dielectric material layer 1015. Technical benefits include mitigation of diffusion of the first metal wiring 1009 and the second metal wiring 1019 to reduce the potential for leakage and to potentially extend a life of the bond. Further, the first dielectric cap 1027 and the second dielectric cap 1029 can potentially reduce an occurrence of voids formed due to metal migration and volume shrinkage after bonding.

Optionally, the semiconductor structure 1001 can include a second dopant material 2025b in the second dielectric cap 1029 and the second metal wiring 1019. Technical benefits include amorphizing the second metal wiring 1019 by implanting the second dopant material 2025b, creating a reduced size of grains in the metal of the second metal wiring 1019 prior to bonding. Reducing the metal grain size in both the first metal wiring 1009 and the second metal wiring 1019, can further reduce a temperature at which bonding can occur and further increase a probability and strength of a bond between an amorphized first interface 2011 of the first metal wiring 1009 and an amorphized second interface 2021 of the second metal wiring 1019. Accordingly, damage to neighboring heat sensitive circuitries can be potentially mitigated and manufacturing process induced mechanical stresses at the bond can be potentially mitigated, reducing opportunities for opens or weakened electrical connections at the bond. Further, implanting the first dopant material 2025a in the second dielectric cap 1029 can create a lower dielectric constant (k) of the second dielectric cap 1029 reducing a possibility of parasitic coupling between the first metal wiring 1009 and the second metal wiring 1019.

In some options, the semiconductor structure 1000 can further include a first liner 1013 between the first metal wiring 1009 and the first dielectric material layer 1005 and a second liner 1023 between the second metal wiring 1019 and the second dielectric material layer 1015. Technical benefits include potential mitigation of diffusion of metal ions from the first metal wiring 1009 and the second metal wiring 1019 into the first dielectric material layer 1005 and second dielectric material layer 1015, respectively, thus potentially increasing a reliability of the first dielectric material layer 1005 and the second dielectric material layer 1015.

In accordance with further aspects of the invention, a semiconductor structure 1000 includes a first sub-structure 1001 having a first dielectric material layer 1005 and a first metal wiring 1009 embedded in the first dielectric material layer; a second sub-structure 1003 having a second dielectric material layer 1015 and a second metal wiring 1019 embedded in the second dielectric material layer 1015; and a first dopant material 2025a in the first dielectric material layer 1005 and in the first metal wiring 1009 of the first sub-structure 1001, in which the first sub-structure 1001 and the second sub-structure 1003 are bonded together at the first dielectric material layer 1005 of the first sub-structure 1001 and the second dielectric material layer 1015 of the second sub-structure 1003 and the first metal wiring 1009 of the first sub-structure 1001 and the second metal wiring 1019 of the second sub-structure 1003. Technical benefits include amorphizing the first metal wiring 1009 by implanting the first dopant material 2025a, creating a reduced size of grains in the metal of the first metal wiring 1009 prior to bonding. Smaller metal grains can increase the probability and strength of a bond between the amorphized first metal wiring 1009 and the second metal wiring 1019, potentially mitigating mechanical stresses at the bond encountered during wafer dicing, singulation, or other operations of the manufacturing process of the semiconductor structure 1000. Potentially, as a result, occurrences of opens or weakened electrical connections between the bonded first metal wiring 1009 and second metal wiring 1019 can be reduced. Further, technical benefits can include a reduction in a temperature at which bonding can occur, for example, achieving a bonding temperature below 350 °C. Reduced temperature bonding can potentially mitigate damage to neighboring heat sensitive circuitry.

Optionally, the semiconductor structure 1000 can include a first dielectric cap 1027 on the first dielectric material layer 1005, in which the first dopant material 2025a can be in the first dielectric cap 1027 and the first dielectric material layer 1005 can be bonded to the second dielectric material layer 1015 at an interface between a dopant-implanted first dielectric cap 1027 located on the first dielectric material layer 1005 and the second dielectric material layer 1015. Technical benefits include mitigation of diffusion of the first metal wiring 1009, reducing a potential for leakage and potentially extending a life of the bond. Further, the first dielectric cap 1027 can potentially reduce an occurrence of voids formed due to metal migration and volume shrinkage after bonding.

In other options, the semiconductor structure 1000 can include a second dielectric cap 1029 on the second dielectric material layer 1015, in which the first dielectric material layer 1005 can be bonded to the second dielectric material layer 1015 at an interface between the first dielectric material layer 1005 and the second dielectric cap 1029 located on the second dielectric material layer 1015. Technical benefits include mitigation of diffusion of the second metal wiring 1019, reducing a potential for leakage and potentially extending a life of the bond. Further, the second dielectric cap 1029 can potentially reduce an occurrence of voids formed due to metal migration and volume shrinkage after bonding.

In still further options, the semiconductor structure 1000 can include a second dopant material 2025b in the second dielectric material layer 1015 and in the second metal wiring 1019 of the second sub-structure 1003. Technical benefits include amorphizing the second metal wiring 1019, creating a reduced size of grains in the metal of the second metal wiring 1019 prior to bonding. Reducing the metal grain size can increase a probability and a strength of a bond between the metal wirings 1009, 1019. Further, mechanical stresses at the bond encountered during operations of the manufacturing process of the semiconductor structure 1000, can be potentially mitigated, reducing a possibility of opens or weakened connections at the bond. Additionally, the smaller grains in both the first metal wiring 1009 and the second metal wiring 1019 can result in a reduction in a temperature at which bonding can occur, potentially mitigating damage to neighboring heat sensitive circuitries.

Still, further in accordance with aspects of the invention, an exemplary method of forming a semiconductor structure 1000 includes ion implanting a dopant material 2025 in at least one of a first dielectric material layer 1005 of a first sub-structure 1001 and a second dielectric material layer 1015 of a second sub-structure 1003; amorphizing, at least in part, at least one of a first metal wiring 1009 embedded in the first dielectric material layer 1005 of the first sub-structure 1001 by ion implanting the dopant material 2025 in a first interface 1011 of the first metal wiring 1009, and a second metal wiring 1019 embedded in the second dielectric material layer 1015 of the second sub-structure 1003 by ion implanting the dopant material 2025 in a second interface 1021 of the second metal wiring 1019; bonding the first dielectric material layer 1005 of the first sub-structure 1001 to the second dielectric material layer 1015 of the second sub-structure 1003; and bonding the first interface 2011 of the first metal wiring 1009 of the first sub-structure 1001 to the second interface 1021 of the second metal wiring 1019 of the second sub-structure 1003. Technical benefits include creating a reduced size of grains in at least one of the metal of the first metal wiring 1009 and the metal of the second metal wiring 1019 prior to bonding. An amorphized first metal wiring 1009 and/or second metal wiring 1019, with smaller metal grains, can increase the probability and strength of a bond between the first interface 2011 of the first metal wiring 1009 and the second interface 1021 of the second metal wiring 1019. Improvements in the bond between the first metal wiring 1009 and the second metal wiring 1019 can mitigate mechanical stresses at the bond encountered during operations of the manufacturing process of the semiconductor structure 1000, potentially reducing occurrences of opens or weakened electrical connections between the bonded first metal wiring 1009 and second metal wiring 1019. Further, due to the smaller grain size of the metal in the first metal wiring 1009 and/or the second metal wiring 1019, technical benefits can include a reduction in a temperature at which bonding can occur, for example, achieving a bonding temperature below 350 °C, potentially mitigating damage to neighboring heat sensitive circuitry.

In still further options, the method for forming the semiconductor structure 1000 can include depositing the first dielectric material layer 1005 of the first sub-structure 1001, patterning the first dielectric material layer 1005 to form a first opening, and depositing a first metal in the first opening to form the first metal wiring 1009; depositing the second dielectric material layer 1015 of the second sub-structure 1003, patterning the second dielectric material layer 1015 to form a second opening, and depositing a second metal in the second opening to form the second metal wiring 1019; and depositing, at least one of: prior to patterning the first dielectric material layer 1005, a first dielectric cap 1027 on the first dielectric material layer 1005, in which forming the first opening can further include patterning the first dielectric cap 1027, and prior to patterning the second dielectric material layer 1015, a second dielectric cap 1029 on the second dielectric material layer 1015, in which forming the second opening can further include patterning the second dielectric cap 1029. Technical benefits include mitigation of diffusion of the first metal wiring 1009 and/or the second metal wiring 1019, reducing a potential for leakage, potentially extending a life of the bond, and potentially reducing an occurrence of voids formed due to metal migration and volume shrinkage after bonding.

In continued options, the method for forming the semiconductor structure 1000 can further include, at least one of, prior to depositing the first metal, depositing a first liner 1013 in the first opening and, prior to depositing the second metal, depositing a second liner 1023 in the second opening. Technical benefits include potential mitigation of diffusion of metal ions from the first metal wiring 1009 and/or the second metal wiring 1019 into the first dielectric material layer 1005 and/or the second dielectric material layer 1015, respectively, thus potentially increasing a reliability of the first dielectric material layer 1005 and/or the second dielectric material layer 1015.

Techniques as disclosed herein can provide substantial beneficial technical effects. Some embodiments may not have these potential advantages, and these potential advantages are not necessarily required of all embodiments. By way of example only and without limitation, one or more embodiments can provide a reduced temperature process (e.g., a bonding temperature below 350 °C) of a metal-to-metal (e.g., copper (Cu-to-Cu)) interface bond of a semiconductor structure during a hybrid bonding process and an improved bond between the metal interfaces, minimizing opens due to mechanical stresses exhibited on the bonded interface during a dicing, singulation, or other operations of the manufacturing process of the semiconductor structure:
by reducing the size of the grains of the metal (e.g., copper (Cu)) in at least one of the two metal interfaces prior to bonding;
by creating, at least in part, an amorphous interface in at least one of the two metal interfaces prior to bonding;
by implanting a dopant material in at least one of the two metal interfaces prior to or at the time of bonding;
by amorphizing, at least in part, one or both of the two metal interfaces to reduce the size of the grains of the metal (e.g., copper (Cu)) prior to bonding; and
by ion implanting one or more atomic species or ionic species, such as fluorine (F), chlorine (Cl), or manganese (Mn) into at least one of the two metal interfaces, amorphizing, at least in part, the interface to reduce the size of the grains of the metal (e.g., copper (Cu)) prior to bonding.

In some scenarios, two or more structures, such as integrated circuits (ICs), dies, chips, wafers or substrates (e.g., glass, silicon, etc. substrate), carriers, interposers, etc., can be stacked and bonded together to form a semiconductor structure (such as in the case of systems on chips (SOCs)). In some embodiments, any number of suitable structures (hereinafter “sub-structures”) can be stacked and bonded together to form the semiconductor structure. A first sub-structure in the semiconductor structure can include an IC, a die, a chip, a wafer or substrate, or the like, and can have one or more device or circuit regions coupled to metal wiring such as metal traces, pads, pillars, patterns, vias, and the like. In some embodiments, a second sub-structure in the semiconductor structure can also include an IC, a die, a chip, a wafer or substrate, etc. In further embodiments, the second sub-structure in the semiconductor structure can include a carrier or an interposer and can have metal wiring such as traces, pads, pillars patterns, vias, and the like.

Metal wiring in the first sub-structure can be embedded in a non-conductive insulator such as a first dielectric material layer and metal wiring in the second sub-structure can be embedded in a non-conductive insulator such as a second dielectric material layer. In some embodiments, the metal wiring in sub-structures can be an electrical and/or thermal path for devices within one or more of the sub-structures, or can be an additional pad, such as a dummy pad used for physical connection between sub-structures and/or balancing of thermal and/or structural connections, though examples are not so limiting. The two sub-structures can be stacked and bonded together so that the first dielectric material layer of the first sub-structure is bonded to the second dielectric material layer of the second sub-structure and the metal wiring of the first sub-structure is bonded to the metal wiring of the second sub-structure. Accordingly, the two sub-structures can be directly bonded together without the use of an intervening adhesive.

During the bonding process, the first dielectric material layer can be bonded to the second dielectric material layer using dielectric-to-dielectric bonding techniques known in the art and further described herein. The metal wiring of the first sub-structure (hereinafter “first metal wiring”), can be bonded to the metal wiring of the second sub-structure (hereinafter “second metal wiring”). Bonding of metal wiring embedded in dielectric material can be accomplished by utilizing heat and pressure during an annealing process. In previous approaches, the temperature used in the annealing process can be substantial, such as approximately 350-400 °C. In some cases, as such bonding is typically done toward the end of fabrication of the semiconductor structure, such substantial temperatures (350-400 °C) can cause damage and/or failure (immediate or latent) to heat sensitive devices, structures, temporary bonds, and/or materials within the semiconductor structure.

One or more embodiments herein advantageously provide for bonding of a first metal wiring of a first sub-structure of a semiconductor structure to a second metal wiring of a second sub-structure of the semiconductor structure at reduced temperatures below 350 °C.

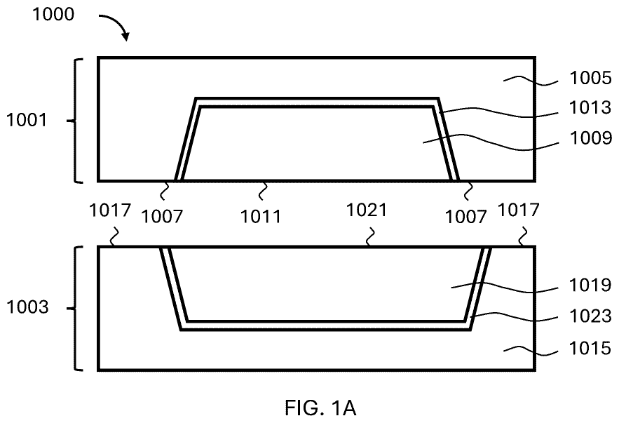

Accordingly, FIG. 1A illustrates a first sub-structure 1001 of a semiconductor structure 1000 and a second sub-structure 1003 of the semiconductor structure 1000 prior to bonding of the first sub-structure 1001 to the second sub-structure 1003. As shown in FIG. 1A, the first sub-structure 1001 can include a first metal wiring 1009. The first metal wiring 1009 can include metal such as copper (Cu), though examples are not so limited. The first metal wiring 1009 can be embedded in a first dielectric material layer 1005. The first dielectric material layer 1005 can include silicon-oxide (SiOₓ), silicon-dioxide (SiO₂), aluminum oxide, etc., though examples are not so limited. In some embodiments, a first liner 1013 can separate the first metal wiring 1009 from the first dielectric material layer 1005. The first liner 1013 can include metal such as titanium-nitride (TiN), tantalum nitride (TaN), etc., though examples are not so limited. It is known in the art that a metal wiring adjacent to a dielectric, such as the first metal wiring 1009 and the first dielectric material layer 1005, can potentially diffuse metal ions into the dielectric, reducing a reliability of the dielectric. Accordingly, a liner can mitigate such diffusion.

The first sub-structure 1001 can be formed utilizing processes known in the art. In one non-limiting example, the first sub-structure 1001 can be formed utilizing a damascene process. That is, levels of a dielectric and a metallic material can be deposited and patterned. For example, in some embodiments, the first dielectric material layer 1005, such as SiO₂, can be deposited. Utilizing processes known in the art, such as, lithography and RIE (reactive ion etching) patterning processes, a portion of the first dielectric material layer 1005 can be etched away to form an opening or a profile for the first metal wiring 1009. The first liner 1013, such as TiN or TaN, can be deposited over the first dielectric material layer 1005. Additionally, in some embodiments, the first liner 1013 can be optional depending on the composition of the first metal wiring 1009 and/or the composition of the first dielectric material layer 1005. Further, metal, such as Cu, can be deposited over the first liner 1013, (or in the case of an absence of the first liner 1013 over the first dielectric material layer 1005) filling the opening or the profile. In some embodiments, excess metal and liner 1013 can be removed and chemical mechanical polishing (CMP) and/or planarization processes can be performed on the first sub-structure 1001. As such, as shown in FIG. 1A, the first metal wiring 1009 can be formed embedded within the first dielectric material layer 1005 and, optionally, separated from the first dielectric material layer 1005 by the first liner 1013.

The second sub-structure 1003 can be formed utilizing processes known in the art, such as a damascene process as previously described, though examples are not limited to a damascene process. The second sub-structure 1003 can include a similar composition to the first sub-structure 1001. The second sub-structure 1003 can include a second metal wiring 1019. The second metal wiring 1019 can be embedded in a second dielectric material layer 1015. In some embodiments, a second liner 1023 can separate the second metal wiring 1019 from the second dielectric material layer 1015, though examples are not so limited and the second liner 1023 can be optional as previously described with reference to the first sub-structure 1001. In some embodiments, the second metal wiring 1019 can be roughly the same size (e.g., width) as the first metal wiring 1009, though examples are not so limited and as illustrated in FIGS. 1A-5, the second metal wiring 1019 can be a different size (e.g., width) as the first metal wiring 1009.

As shown in FIG. 1A, the first sub-structure 1001 can include a first surface 1007 and a first interface 1011. In some embodiments, the first sub-structure 1001 can be fabricated such that a surface of the first interface 1011 (located at a surface of the first metal wiring 1009) is flush with the first surface 1007 (a surface of the first dielectric material layer 1005 as shown in FIG. 1A). In further embodiments, the first sub-structure 1001 can be fabricated such that the surface of the first interface 1011 is recessed relative to the first surface 1007. In some embodiments, the first surface 1007 and the first interface 1011 can be cleaned to remove impurities and/or undesirable compounds and/or polished (e.g., CMP process, or the like) to remove any roughness and create a smooth, flat surface for bonding.

As further shown in FIG. 1A, the second sub-structure 1003 can include a second surface 1017 and a second interface 1021. In some embodiments, the second sub-structure 1003 can be fabricated such that a surface of the second interface 1021 (located at a surface of the second metal wiring 1019) is flush with the second surface 1017 (a surface of the second dielectric material layer 1015 as shown in FIG. 1A). In further embodiments, the second sub-structure 1003 can be fabricated such that the surface of the second interface 1021 is recessed relative to the second surface 1017. Further, the second surface 1017 and the second interface 1021 can be cleaned to remove impurities and/or undesirable compounds and/or polished (e.g., CMP process, or the like) to remove any roughness and create a smooth, flat surface for bonding.

FIG. 1B illustrates an exemplary embodiment in which a first sub-structure 1001 of a semiconductor structure 1000 includes a first dielectric cap 1027. The first dielectric cap 1027 can be deposited on a first dielectric material layer 1005 of the first sub-structure 1001 as shown in FIG. 1B. For example, the first sub-structure 1001 can be formed utilizing processes known in the art such as a damascene process. That is, the first dielectric material layer 1005 can be deposited. The first dielectric cap 1027 can be deposited over the first dielectric material layer 1005 and a patterning process can be performed. A portion of the first dielectric material layer 1005 and first dielectric cap 1027 can be etched away to form an opening or a profile for a first metal wiring 1009. An optional first liner 1013, can be deposited over the first dielectric material layer 1005 and first dielectric cap 1027 and metal, such as Cu, can be deposited over the first liner 1013, filling the opening or the profile. Excess metal and liner 1013 can be removed and chemical mechanical polishing (CMP) and/or other planarization processes can be performed on the first sub-structure 1001. In some embodiments, the first dielectric cap 1027 can include silicon-nitride (SiN), though examples are not so limited. Further, in some embodiments, the first dielectric cap 1027 can be optional.

As shown in FIG. 1B, the first sub-structure 1001 can include a first surface 1007 and a first interface 1011. In some embodiments, the first sub-structure 1001 can be fabricated such that a surface of the first interface 1011 (located at a surface of the first metal wiring 1009) is flush with the first surface 1007 (a surface of the first dielectric cap 1027 as shown in FIG. 1B), though examples are not so limited.

FIG. 1C illustrates an exemplary embodiment in which a first sub-structure 1001 of a semiconductor structure 1000 includes a first dielectric cap 1027 and a second sub-structure 1003 of the semiconductor structure 1000 includes a second dielectric cap 1029. In some embodiments, the first dielectric cap 1027 and the second dielectric cap 1029 can be formed utilizing processes known in the art, such as a damascene process as previously described in reference to the formation of the first dielectric cap 1027 in FIG. 1B, though examples are not limited. In some embodiments, the first dielectric cap 1027 and the second dielectric cap 1029 can include silicon-nitride (SiN), though examples are not so limited. Further, the first dielectric cap 1027 can include the same or different material than the second dielectric cap 1029. In still further embodiments, the first dielectric cap 1027, the second dielectric cap 1029, or both can be optional.

As shown in FIG. 1C, the first sub-structure 1001 can include a first surface 1007 and a first interface 1011 and the second sub-structure 1003 can include a second surface 1017 and a second interface 1021. In some non-limiting embodiments, a surface of the first interface 1011 (located at a surface of a first metal wiring 1009) can be flush with the first surface 1007 (a surface of the first dielectric cap 1027 as shown in FIG. 1C) and a surface of the second interface 1021 (located at a surface of a second metal wiring 1019) can be flush with the second surface 1017 (a surface of the second dielectric cap 1029 as shown in FIG. 1C). In some embodiments, the first surface 1007, the first interface 1011, the second surface 1017, and the second interface 1021 can be cleaned to remove impurities and/or undesirable compounds and/or polished (e.g., CMP process, or the like) to remove any roughness and create a smooth, flat surface for bonding.

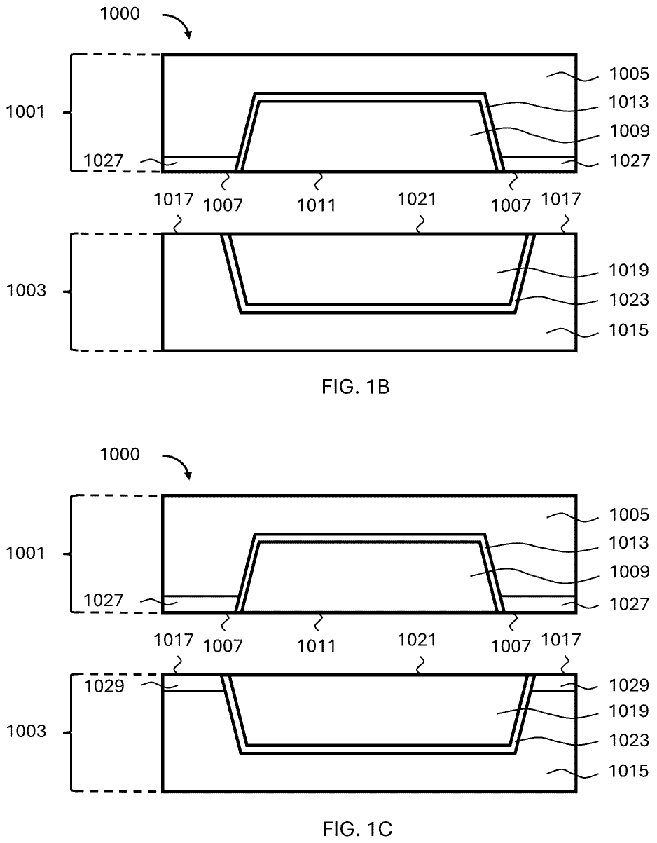

Turning now to FIGS. 2A-2B, a first dopant material 2025a can be implanted (e.g., ion implanted) in a first sub-structure 1001 of a semiconductor structure 1000. In some embodiments, the first dopant material 2025a can include fluorine (F) chlorine (Cl), or manganese (Mn). Further, in some embodiments, the first dopant material 2025 a can have a concentration of less than 5 atomic percentage of an implanted volume, though examples are not so limited. For example, if the Cu (of a first metal wiring 1009 and/or a second metal wiring 1019) has a wire atomic density of 8.49×10²⁸ atoms/m³ and 1×10¹⁹ F atoms/m² ion fluence is implanted to a depth of 5 nm (i.e., 0.000000005 m), an ion concentration of 2×10²⁷ F atoms/m³ and ion atomic percentage in the Cu of 2.3 at % (atomic percentage) F can be observed.

As shown in FIGS. 2A-2B, the first dopant material 2025a can be ion implanted in a first surface (i.e., first surface 1007 as shown in FIGS. 1A-1C) and in a first interface (i.e., first interface 1011 as shown in FIGS. 1A-1C) of the first sub-structure 1001, creating a dopant-implanted first surface 2007 and a dopant-implanted first interface 2011, respectively. The first dopant material 2025a implanted in the first surface 2007 can be implanted in a first dielectric material layer 1005 of the first sub-structure 1001. In some embodiments as illustrated in FIGS. 2A-2B, the first sub-structure 1001 can include a first dielectric cap 1027. In such embodiments, the first dopant material 2025a implanted in the first surface 2007 can be implanted in the first dielectric cap 1027 located on the first dielectric material layer 1005 of the first sub-structure 1001. However, embodiments are not so limited and the first dielectric cap 1027 can be optional. Further, the first dopant material 2025a implanted in the first interface can be implanted in a surface of the first metal wiring 1009 of the first sub-structure 1001.

Ion implantation of the first dopant material 2025a can lower a dielectric constant (k) of the first dielectric material layer 1005 and/or the first dielectric cap 1027. A lower dielectric constant can reduce the possibility of parasitic coupling between conductive features of the semiconductor structure 1000, such as the first metal wiring 1009 and a potential adjacent conductive feature within the semiconductor structure 1000. Further, ion implantation of the first dopant material 2025a can cause the first metal wiring 1009 to, at least in part, amorphize. Thus, the dopant-implanted first interface 2011 can also be an amorphized (at least in part) first interface 2011.

Causing the first metal wiring 1009 to, at least in part, amorphize can yield advantageous results. Metals that can be used for the first metal wiring 1009, such as Cu, can include grains. A zsie of the grains can affect the probability of successful bonding, bonding strength, and a temperature at which bonding can occur. Amorphizing the first metal wiring 1009 can cause the grains within the dopant-implanted first interface 2011 of the first metal wiring 1009 to be smaller than prior to ion implantation. Small grains at a bonding interface can enable a greater number of grain boundaries at the bonding interface than with larger grains and, thus, can increase a probability of forming a bond. Additionally, metals with relatively small grains can bond with a relatively high bonding strength even with a reduced annealing temperature. Further, according to the Gibbs-Thomson effect known in the art, smaller grains of an amorphized metal can be in equilibrium with a liquid state of the metal, thus yielding a lower temperature melting point. In addition, for any given annealing temperature, the bonding strength of a small grain metal wiring can often be greater than a bonding strength of a single crystal or a large grain metal wiring.

In some embodiments, the first dopant material 2025a can be implanted (e.g., ion implanted) in a second sub-structure 1003 of the semiconductor structure 1000, as shown in FIG. 2A. Alternatively, in still other embodiments, a second dopant material 2025b can be implanted (e.g., ion implanted) in the second sub-structure 1003 of the semiconductor structure 1000, as shown in FIG. 2B. In some examples, the second dopant material 2025b can be a different material than the first dopant material 2025a. The first dopant material 2025a, as shown in FIG. 2A or the second dopant material 2025b, as shown in FIG. 2B, can be ion implanted in a second surface (i.e., second surface 1017 as shown in FIGS. 1A-1C) and in a second interface (i.e., second interface 1021 as shown in FIGS. 1A-1C) of the second sub-structure 1003, creating a dopant-implanted second surface 2017 and a dopant-implanted second interface 2021 (or amorphized, at least in part, second interface 2021), respectively. Ion implantation of the first dopant material 2025a or the second dopant material 2025b can lower a dielectric constant (k) of a second dielectric material layer 1015 and can cause the second metal wiring 1019 to, at least in part, be amorphized.

In some embodiments as illustrated in FIGS. 2A-2B, the second sub-structure 1003 can include a second dielectric cap 1029. In such embodiments, the first dopant material 2025a, as shown in reference to FIG. 2A, or the second dopant material 2025b, as shown in reference to FIG. 2B, implanted in the second surface 1017, can be implanted in the second dielectric cap 1029 located on the second dielectric material layer 1015 of the second sub-structure 1003. However, embodiments are not so limited and the second dielectric cap 1029 can be optional. Further, the dopant material implanted in the second interface 1021 can be implanted in the surface of the second metal wiring 1019 of the second sub-structure 1003.

Though FIGS. 2A-2B illustrate an ion implanted first sub-structure 1001 and second sub-structure 1003 of the semiconductor structure 1000, examples are not so limited and some embodiments can be ion implanted in one of the first sub-structure 1001 or the second sub-structure 1003.

Accordingly, FIG. 2A illustrates the first dopant material 2025a implanted in the first sub-structure 1001 and the second sub-structure 1003 and FIG. 2B illustrates the first dopant material 2025a implanted in the first sub-structure 1001 and the second dopant material 2025b implanted in the second sub-structure 1003. As previously stated, the second dopant material 2025b can include different material than the first dopant material 2025a (as illustrated in FIG. 2B by the differing shading of the dopant-implanted first surface 2007 and the dopant-implanted first interface 2011 as compared to the dopant-implanted second surface 2017 and the dopant-implanted second interface 2021).

Accordingly, the first metal wiring 1009, can be, at least partially, amorphized to create a smaller grain Cu interface (e.g., dopant-implanted first interface 2011 of the first metal wiring 1009) and the second metal wiring 1019 can include the larger Cu grain of a non-dopant-implanted interface (e.g., second interface 1021 of the second metal wiring 1019, as shown in FIGS. 1A-1C), or vice versa. Alternatively, both the first metal wiring 1009 and the second metal wiring 1019 can be ion implanted and, at least partially, amorphized to create the smaller grain Cu interfaces: dopant-implanted first interface 2011 and dopant-implanted second interface 2021, as shown in FIGS. 2A-2B.

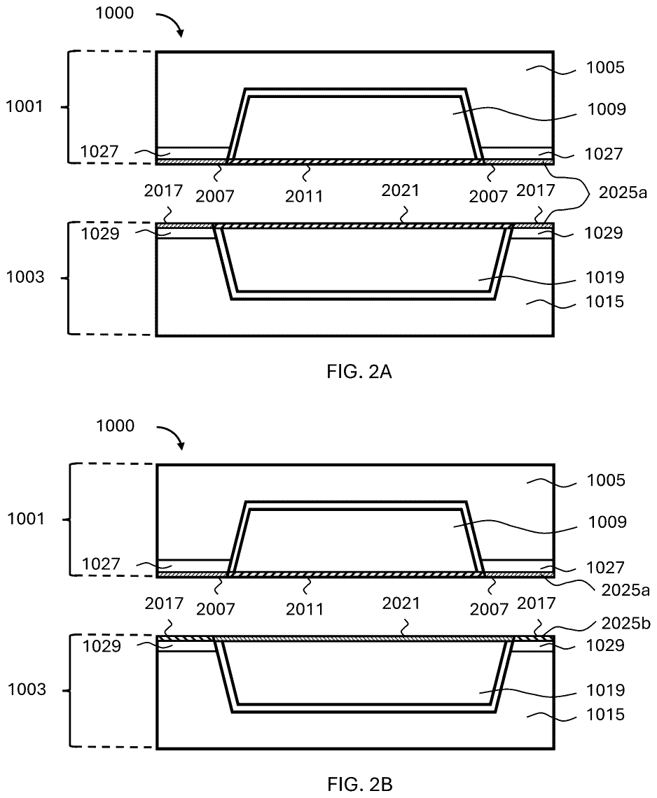

FIGS. 3A and 3B illustrate an exemplary embodiment including a first sub-structure 1001 of a semiconductor structure 1000 including a dopant-implanted first interface 2011 embedded in a first dielectric material layer 1005 and an optional first dielectric cap 1027 and a second sub-structure 1003 of the semiconductor structure 1000 including a dopant-implanted second interface 2021 embedded in a second dielectric material layer 1015 and an optional second dielectric cap 1029. FIG. 3A illustrates a first dopant material 2025a implanted in both a first metal wiring 1009 of the first sub-structure 1001 and a second metal wiring 1019 of the second sub-structure 1003; however, examples are not so limited and the first dopant material 2025a can be implanted in the first metal wiring 1009, the second metal wiring 1019, or both (not illustrated for brevity). Further, FIG. 3B illustrates the first dopant material 2025a implanted in the first metal wiring 1009 of the first sub-structure 1001 and a second dopant material 2025b implanted in the second metal wiring 1019 of the second sub-structure 1003; however, examples are not so limited. For example, in some embodiments, the second dopant material 2025b can be implanted in both the first metal wiring 1009 and the second metal wiring 1019 (not illustrated for brevity).

That is, in some non-limiting embodiments, a cap (e.g., such as a tantalum oxide (TaOₓ), SiO₂, etc. cap) can be selectively grown over a first surface 1007 of the first dielectric material layer 1005 (and optional first dielectric cap 1027) and/or over a second surface 1017 of the second dielectric material layer 1015 (and optional second dielectric cap 1029) (selectively grown cap not shown for brevity). The first interface (i.e., first interface 1011 as shown in FIGS. 1A-1C) and/or the second interface (i.e., second interface 1021 as shown in FIGS. 1A-1C) can be ion implanted with the first dopant material 2025a or second dopant material 2025b, and the selectively grown cap can be removed from the first surface 1007 and/or second surface 1017. Accordingly, the first sub-structure 1001 can include the first metal wiring 1009 with a dopant-implanted first interface 2011, embedded in a non-dopant-implanted first dielectric material layer 1005 and the optional first dielectric cap 1027 and the second sub-structure 1003 can include the second metal wiring 1019 with a dopant-implanted second interface 2021, embedded in a non-dopant-implanted second dielectric material layer 1015 and the optional second dielectric cap 1029.

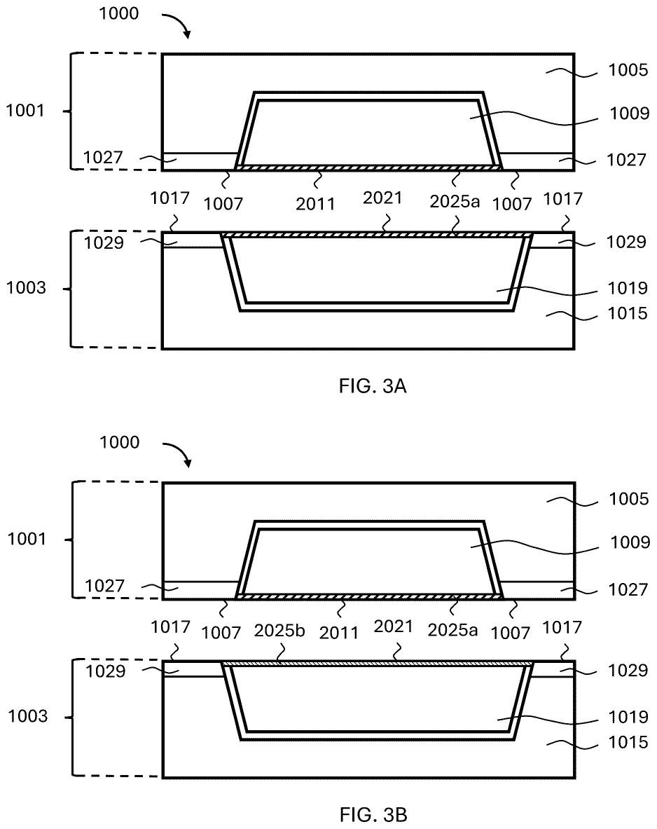

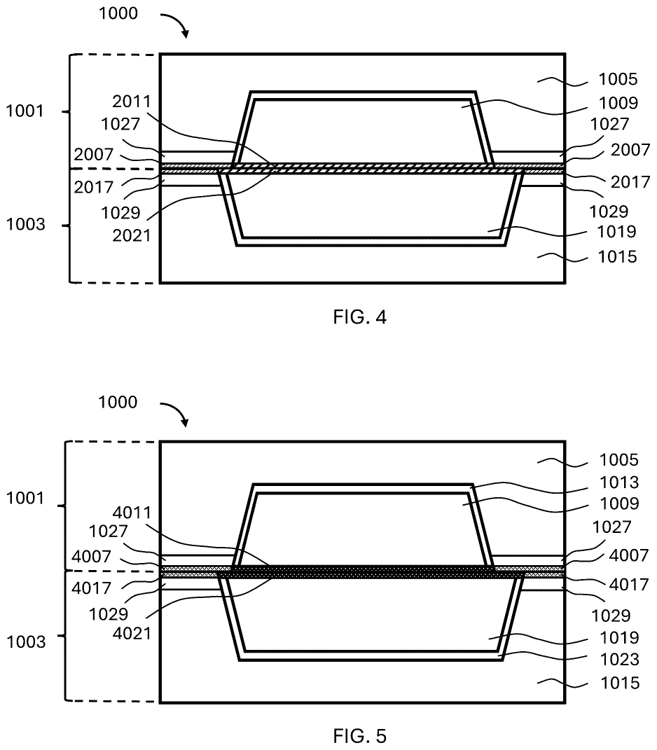

Turning now to FIGS. 4-5, a first dielectric material layer 1005 and a first metal wiring 1009 of a first sub-structure 1001 of a semiconductor structure 1000 can be stacked on a second dielectric material layer 1015 and a second metal wiring 1019 of a second sub-structure 1003 of the semiconductor structure 1000.

A first surface of the first sub-structure 1001 can be brought into physical contact with a second surface of the second sub-structure 1003 and a first interface of the first sub-structure 1001 can be brought into physical contact with the second interface of the second sub-structure 1003. In some embodiments, as illustrated in FIG. 4, the first surface of the first sub-structure 1001 can be a dopant-implanted first surface 2007 and the first interface of the first sub-structure 1001 can be a dopant-implanted first interface 2011, and the second surface of the second sub-structure 1003 can be a dopant-implanted second surface 2017 and the second interface of the second sub-structure 1003 can be a dopant-implanted second interface 2021. However, examples are not so limiting and in some embodiments the first surface and/or first interface can be non-dopant implanted (e.g., first surface 1007 and first interface 1011, as shown in reference to FIGS. 1A-1C) or the second surface and/or the second interface can be non-dopant implanted (e.g., second surface 1017 and second interface 1021, as shown in reference to FIGS. 1A-1C). Further, as shown in FIG. 4, the dopant-implanted first surface 2007 and dopant-implanted first interface 2011 can include the same dopant material as the dopant-implanted second surface 2017 and dopant-implanted second interface 2021 (as previously described in reference to FIG. 2A). However, in some embodiments, the dopant-implanted first surface 2007 and dopant-implanted first interface 2011 can include different dopant material as the dopant-implanted second surface 2017 and dopant-implanted second interface 2021 (as previously described in reference to FIG. 2B).

FIGS. 4-5 further illustrate a first dielectric cap 1027 on the first dielectric material layer 1005 and at the first surface, and a second dielectric cap 1029 on the second dielectric material layer 1015 and at the second surface. However, it is to be understood that in some embodiments the first dielectric cap 1027 and/or the second dielectric cap 1029 can be optional.

In some embodiments, the dielectric at the first surface (first dielectric material layer 1005, or optionally the first dielectric cap 1027 located on the first dielectric material layer 1005) and/or the dielectric at the second surface (second dielectric material layer 1015, or optionally the second dielectric cap 1029 located on the second dielectric material layer 1015) can be activated using plasma processes known in the art. The plasma process can create a chemical reaction resulting in dangling bonds (or covalent bonds) across the contact area between the dielectric at the first surface and the dielectric at the second surface that can cause the two dielectrics (i.e., the first dielectric material layer 1005, or optionally the first dielectric cap 1027 located on the first dielectric material layer 1005 and the second dielectric material layer 1015, or optionally the second dielectric cap 1029 located on the second dielectric material layer 1015) to bond together. As shown in FIG. 5, the surface of the first sub-structure 1001 can bond to the surface of the second sub-structure 1003 creating a bonded first surface 4007 and a bonded second surface 4017 at an interface between the first dielectric material layer 1005 (or the first dielectric cap 1027 located on the first dielectric material layer 1005) and the second dielectric material layer 1015 (or at the second dielectric cap 1029 located on the second dielectric material layer 1015). Over a period of time, the dangling bonds can increase from the chemical reaction and strengthen the bond between the dielectrics. In some embodiments, a degassing process can be utilized to remove excess volatile moieties from the dopant implant, but at sufficiently low temperature (e.g., ≤300 C°) to maintain an amorphous, at least in part, metal.

As previously described, the first sub-structure 1001 can optionally include the first dielectric cap 1027. The first dielectric cap 1027 can minimize diffusion of the first metal wiring 1009 (i.e., copper from diffusing through a bonding interface), to reduce the potential for leakage and to potentially extend a life of a bond. Accordingly, the first dielectric cap 1027 can potentially reduce an occurrence of voids that can be formed due to copper migration and volume shrinkage after bonding. Further, the second sub-structure 1003 can optionally include the second dielectric cap 1029. The second dielectric cap 1029 can minimize diffusion of the second metal wiring 1019 reducing a potential for leakage and potentially extending a life of the bond. Accordingly, the second dielectric cap 1029 can potentially reduce an occurrence of voids formed due to copper migration and volume shrinkage after bonding.

As previously described, the size (e.g., width) of the second metal wiring 1019 can, in some embodiments, be different than the size (e.g., width) of the first metal wiring 1009. FIGS. 1A-5 illustrate the second metal wiring 1019 with a greater width than the first metal wiring 1009. Accordingly, bonding of the semiconductor structure 1000 can cause a portion of the non-conductive dielectric material (e.g., first dielectric material layer 1005, or optional first dielectric cap 1027 located on the first dielectric material layer 1005) to contact a portion of the conductive metal wiring (e.g., second metal wiring 1019). As such, during bonding processes, non-conductive material, such as the first dielectric material layer 1005 or, optionally, the first dielectric cap 1027 located on the first dielectric material layer 1005, can be directly bonded to conductive material, such as the second metal wiring 1019. In the same way, in some embodiments it can be contemplated that the first metal wiring 1009 can be directly bonded to the second dielectric material layer 1015 or, optionally, the second dielectric cap 1029 located on the second dielectric material layer 1015.

The first metal wiring 1009 of the first sub-structure 1001 and the second metal wiring 1019 of the second sub-structure 1003 of can be bonded together. As illustrated in FIG. 5, the first metal wire 1009 can be bonded to the second metal wire 1019 to form a bonded first interface 4011 and a bonded second interface 4021 at an interface between the first metal wiring 1009 and the second metal wiring 1019. Pressure can be applied to the semiconductor structure 1000 to press the first metal wiring 1009 and the second metal wiring 1019 toward each other. Additionally, heat can be applied to the semiconductor structure 1000 through an annealing process. As the semiconductor structure 1000 is heated, the first dielectric material layer 1005 (and, optionally, the first dielectric cap 1027 located on the first dielectric material layer 1005), the second dielectric material layer 1015 (and, optionally, the second dielectric cap 1029 located on the second dielectric material layer 1015), the first metal wiring 1009, and second metal wiring 1019 will expand. As the first metal wiring 1009 and the second metal wiring 1019 expand into each other and the pressure applied to the semiconductor structure 1000 prevents the first metal wiring 1009 and the second metal wiring 1019 from moving away from each other, a direct physical and often an electrical bond can be formed. A surface of the first metal wiring 1009 (first interface 1011, as shown in FIGS. 1A-1C, or dopant-implanted first interface 2011, as shown in FIGS. 2A-4) and a surface of the second metal wiring 1019 (second interface 1021, as shown in FIGS. 1A-1C, or dopant-implanted second interface 2021, as shown in FIGS. 2A-4) can wet and bond together to form a bonded interface (e.g., bonded first interface 4011 and bonded second interface 4021, as shown in FIG. 5). Grains of the first metal wiring 1009 and grains of the second metal wiring 1019 can grow into each other across the bonded interface, forming one metal structure.

As previously described, a smaller grain size of the metal in the first metal wiring 1009, the second metal wiring 1019, or both, can yield a better probability of bonding and a better bonding strength. Improved bonding strength can result in a reduction in mechanical stress during manufacturing processes, such as wafer or substrate dicing and singulation or other operations, which can cause fracturing of the bond and opens (open circuits) between metal interconnections. Further, a temperature at which bonding occurs between the two metals can be reduced. That is a first interface (e.g., first interface 1011, as shown in FIGS. 1A-1C) of the first metal wiring 1009, the second interface (e.g., second interface 1021, as shown in FIGS. 1A-1C) of the second metal wiring 1019, or both, can be ion implanted with a dopant material to amorphize the first metal wiring 1009, the second metal wiring 1019, or both, respectively, reducing a grain size of the first metal wiring 1009, the second metal wiring 1019, or both, respectively. Due to the amorphization, a low temperature sintering of the metal can be achieved. In some embodiments, the temperature at which bonding occurs can be reduced by 100-200 °C. Ion implanting both the first interface of the first metal wiring 1009 and the second interface of the second metal wiring 1019 can yield a greater potential for bonding and a greater bonding strength at a lower bonding temperature than ion implantation of the dopant material in one of the two metal wirings 1009, 1019 alone. Accordingly, a bonding temperature below 350 °C can be achieved. In some embodiments, a bonding temperature reduction to between 200 °C and 300 °C can be achieved.

A coefficient of thermal expansion (CTE) can be different between metals and dielectric materials. Most metals, like copper (Cu) can have a higher CTE than dielectric materials such as silicon (Si) or silicon-oxides such as SiO or SiO₂. As such, in some cases, during an annealing process, the first metal wiring 1009 and the second metal wiring 1019 can expand not only into each other, forming a direct mechanical bond, but can expand so as to press against the dielectric material (first dielectric material layer 1005 and second dielectric material layer 1015, and optional first dielectric cap 1027 located on the first dielectric material layer 1005 and second dielectric cap 1029 located on the second dielectric material layer 1015) in which the first metal wiring 1009 and the second metal wiring 1019 are embedded. In some non-limiting cases, such thermal expansion mismatch can cause stresses on the already bonded dielectric materials (first dielectric material layer 1005 and second dielectric material layer 1015, and optional first dielectric cap 1027 located on the first dielectric material layer 1005 and second dielectric cap 1029 located on the second dielectric material layer 1015) resulting in a potential for partial delamination of the dielectric bond. A reduction in annealing temperature can minimize an effect of the differing CTE between metals and dielectric materials.

Further, in some embodiments, prior to bonding, the first metal wiring 1009 and/or second metal wiring 1019 can be recessed (not shown) in respect to a first surface (e.g., first surface 1007, as shown in FIGS. 1A-1C, or first surface 2007, as shown in FIGS. 2A-4) and/or a second surface (e.g., second surface 1017, as shown in FIGS. 1A-1C, or second surface 2017, as shown in FIGS. 2A-4), respectively. The first metal wiring 1009 and/or second metal wiring 1019 can be recessed to a degree such that during the annealing process, the first metal wiring 1009 and the second metal wiring 1019 can expand, filling the recessed area and bonding to one another. Accordingly, the recessed area can accommodate the expansion of the first metal wiring 1009 and the second metal wiring 1019 minimizing the potential of stress exerted on the dielectric bond during the annealing process without jeopardizing a bonding potential or strength of the metal bond.

In some embodiments, at least one of the first metal wiring 1009 and first dielectric (first dielectric material layer 1005 or optional first dielectric cap 1027 located on the first dielectric material layer 1005) and the second metal wiring 1019 and second dielectric (second dielectric material layer 1015 or optional second dielectric cap 1029 located on the second dielectric material layer 1015) can be ion implanted with the dopant material and bonded together. FIG. 5 illustrates an example of the semiconductor structure 1000 with both the first metal wiring 1009 and first dielectric (first dielectric material layer 1005 or optional first dielectric cap 1027 located on the first dielectric material layer 1005) and the second metal wiring 1019 and second dielectric (second dielectric material layer 1015 or optional second dielectric cap 1029 located on the second dielectric material layer 1015) ion implanted with the dopant material and bonded together; however, as previously described, examples are not so limited.

The bond between the first metal wiring 1009 and the second metal wiring 1019 can extend across an interface between the first metal wiring 1009 and the second metal wiring 1019 such that there can be substantially no gap between the first metal wiring 1009 and the second metal wiring 1019 and, thus, substantially no gap between the bonded conductive metal wirings 1009, 1019 and the bonded non-conductive dielectrics (e.g., dielectric materials 1005, 1015 or optional dielectric caps 1027, 1029 of the dielectric materials 1005, 1015). Additionally, as shown in FIG. 5, in the case where the first metal wiring 1009 is of a different size (e.g., width) than the second metal wiring 1019, a portion of the first dielectric material layer 1005 or, optionally, the first dielectric cap 1027 located on the first dielectric material layer 1005 can be bonded to a portion of the second metal wiring 1019. Though not shown in the figures for simplicity, examples are not so limited; however, and in some embodiments, the first metal wiring 1009 can have a greater width than the second metal wiring 1019 or the first metal wiring 1009 and the second metal wiring 1019 can be stacked off center creating an overlap between dielectric materials (e.g., dielectric materials 1005, 1015 or optional dielectric caps 1027, 1029 of the dielectric materials 1005, 1015) and the first metal wiring 1009 and/or the second metal wiring 1019 and, thus, a portion of the second dielectric material layer 1015 or, optionally, the second dielectric cap 1029 located on the second dielectric material layer 1015 can be bonded to a portion of the first metal wiring 1009. Thus, the semiconductor structure 1000 can be bonded or hybrid bonded (dielectric-to-dielectric, metal-to-metal, and/or dielectric-to-metal) to form one concise 3D package.

Accordingly, FIG. 5 illustrates the semiconductor structure 1000 with two sub-structures, ion implanted with a dopant material (dopant material 2025, as described in reference to FIG. 2A or dopant material 2025a and 2025b, as described in reference to FIG. 2B), and bonded together forming one concise 3D package. The semiconductor structure 1000 includes the first metal wiring 1009 and the second metal wiring 1019 bonded together at a bonded dopant-implanted interface of the first metal wiring 1009 of the first sub-structure 1001 and the second metal wiring 1019 of the second sub-structure 1003. The first metal wiring 1009 can be embedded in the first dielectric material layer 1005 and the optional first dielectric cap 1027 and optionally separated from the first dielectric material layer 1005 and the optional first dielectric cap 1027 by a first liner 1013. The second metal wiring 1019 can be embedded in the second dielectric material layer 1015 and the optional second dielectric cap 1029 and optionally separated from the second dielectric material layer 1015 and the optional second dielectric cap 1029 by a second liner 1023. The first dielectric material layer 1005 (or the optional first dielectric cap 1027 located on the first dielectric material layer 1005) and the second dielectric material layer 1015 (or the optional second dielectric cap 1029 located on the second dielectric material layer 1015) can be bonded together at a bonded dopant-implanted interface of the first dielectric material layer 1005 (or the optional first dielectric cap 1027 located on the first dielectric material layer 1005) of the first sub-structure 1001 and the second dielectric material layer 1015 (or the optional second dielectric cap 1029 located on the second dielectric material layer 1015) of the second sub-structure 1003. Though not illustrated for simplicity, optionally, as previously described herein, one of the two sub-structures can be ion implanted with a dopant material in a surface of a dielectric material layer (or optional dielectric cap located on the dielectric material layer) and/or in an interface of a metal wiring and the other sub-structure can be non-doped.

Applications of the embodiments described herein include, but are not limited to, vertical integration of integrated circuitry (ICs) for 3D packaging, such as 3D SOC; micro-pad packaging; high-performance and low cost flip-chip bonding; wafer-to-wafer bonding; die-to-die bonding; wafer-to-die bonding; wafer scale packaging; and thermal management of semiconductor structures including metal base devices.

As used herein, “epitaxial” deposition means the growth of a material on a deposition surface in which the material being grown has the same crystalline characteristics as the deposition surface. In an epitaxial deposition process, the chemical reactants are controlled and the system parameters are set so that the atoms being deposited arrive at the deposition surface of the semiconductor substrate with sufficient energy to move around on the surface and orient themselves to the crystal arrangement of the atoms of the deposition surface.

The drawing figures as discussed above depict exemplary processing steps/stages in the fabrication of exemplary structures. Although the overall fabrication methods and the structures formed thereby are entirely novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications including, for example: James D. Plummer et al., Silicon VLSI Technology: Fundamentals, Practice, and Modeling 1^{st} Edition, Prentice Hall, 2001 and P.H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices or other layers may not be explicitly shown in a given figure for ease of explanation. This does not imply that the semiconductor layer(s) or other layer(s) not explicitly shown are omitted in the actual integrated circuit device.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

At least a portion of the techniques described above can be implemented in an integrated circuit. Forming integrated circuits, identical dies are typically fabricated in a repeated pattern on a surface of a semiconductor wafer. Each die includes a device described herein and may include other structures and/or circuits. The individual dies are cut or diced from the wafer, then packaged as an integrated circuit. One skilled in the art would know how to dice wafers and package die to produce integrated circuits.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from having structures such as memory devices including sub-structures formed in accordance with one or more of the exemplary embodiments.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods can occur out of the order noted in the figures. For example, two steps shown in succession may, in fact, be executed substantially concurrently, or certain steps can sometimes be executed in the reverse order, depending upon the functionality involved. The drawings are also merely representational and, as previously stated, are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose may be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom,” “top,” “above,” “over,” “under,” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a first dielectric material layer;
a first metal wiring embedded in the first dielectric material layer;
a second dielectric material layer;
a second metal wiring embedded in the second dielectric material layer; and
a first dopant material in the first metal wiring,
wherein, the first dielectric material layer is bonded to the second dielectric material layer and the first metal wiring is bonded to the second metal wiring.

2. The structure of claim 1, further comprising the first dopant material in the first dielectric material layer.

3. The structure of claim 1, wherein the first metal wiring has a same width as the second metal wiring and the first metal wiring is fully aligned with the second metal wiring.

4. The structure of claim 1, wherein the first dielectric material layer overlaps and is bonded to, at least in part, the second metal wiring, the second dielectric material layer overlaps and is bonded to, at least in part, the first metal wiring, or both.

5. The structure of claim 1, wherein the first dopant material has a concentration of less than 5 atomic percentage of an implanted volume and the first dopant material is selected from the group consisting of:
fluorine (F);
chlorine (Cl); and
manganese (Mn).

6. The structure of claim 1, further comprising a second dopant material in the second metal wiring.

7. The structure of claim 6, wherein the second dopant material includes a same material as the first dopant material.

8. The structure of claim 6, wherein the second dopant material includes a different material than the first dopant material, the second dopant material has a concentration of less than 5 atomic percentage of an implanted volume, and the second dopant material is selected from the group consisting of:
fluorine (F);
chlorine (Cl); and
manganese (Mn).

9. The structure of claim 1, comprising a first dielectric cap on the first dielectric material layer, wherein:
the first dopant material is in the first dielectric cap; and
the first dielectric material layer is bonded to the second dielectric material layer via the first dielectric cap at an interface between the first dielectric cap located on the first dielectric material layer and the second dielectric material layer.

10. The structure of claim 9, comprising a second dopant material in the second dielectric material layer and the second metal wiring.

11. The structure of claim 1, comprising a second dielectric cap on the second dielectric material layer,
wherein the first dielectric material layer is bonded to the second dielectric material layer at an interface between the first dielectric material layer and the second dielectric cap located on the second dielectric material layer.

12. The structure of claim 1, comprising a first dielectric cap on the first dielectric material layer, and a second dielectric cap on the second dielectric material layer, wherein:
the first dopant material is in the first dielectric cap; and
the first dielectric material layer is bonded to the second dielectric material layer at an interface between the first dielectric cap located on the first dielectric material layer and the second dielectric cap located on the second dielectric material layer.

13. The structure of claim 12, comprising a second dopant material in the second dielectric cap and the second metal wiring.

14. The structure of claim 1, further comprising a first liner between the first metal wiring and the first dielectric material layer and a second liner between the second metal wiring and the second dielectric material layer.

15. A semiconductor structure, comprising:
a first sub-structure comprising:
a first dielectric material layer; and
a first metal wiring embedded in the first dielectric material layer;
a second sub-structure comprising:
a second dielectric material layer; and
a second metal wiring embedded in the second dielectric material layer; and
a first dopant material in the first dielectric material layer and in the first metal wiring of the first sub-structure,
wherein the first sub-structure and the second sub-structure are bonded together at:
the first dielectric material layer of the first sub-structure and the second dielectric material layer of the second sub-structure; and
the first metal wiring of the first sub-structure and the second metal wiring of the second sub-structure.

16. The structure of claim 15, comprising a first dielectric cap on the first dielectric material layer, wherein:
the first dopant material is in the first dielectric cap; and
the first dielectric material layer is bonded to the second dielectric material layer at an interface between a dopant-implanted first dielectric cap located on the first dielectric material layer and the second dielectric material layer.

17. The structure of claim 15, comprising a second dielectric cap on the second dielectric material layer, wherein the first dielectric material layer is bonded to the second dielectric material layer at an interface between the first dielectric material layer and the second dielectric cap located on the second dielectric material layer.

18. The structure of claim 15, comprising a second dopant material in the second dielectric material layer and in the second metal wiring of the second sub-structure.

19. A method for forming a semiconductor structure, the method comprising:
ion implanting a dopant material in at least one of a first dielectric material layer of a first sub-structure and a second dielectric material layer of a second sub-structure;
amorphizing, at least in part, at least one of:
a first metal wiring embedded in the first dielectric material layer of the first sub-structure by ion implanting the dopant material in a first interface of the first metal wiring; and
a second metal wiring embedded in the second dielectric material layer of the second sub-structure by ion implanting the dopant material in a second interface of the second metal wiring;
bonding the first dielectric material layer of the first sub-structure to the second dielectric material layer of the second sub-structure; and
bonding the first interface of the first metal wiring of the first sub-structure to the second interface of the second metal wiring of the second sub-structure.

20. The method of claim 19, further comprising:
depositing the first dielectric material layer of the first sub-structure, patterning the first dielectric material layer to form a first opening, and depositing a first metal in the first opening to form the first metal wiring;
depositing the second dielectric material layer of the second sub-structure, patterning the second dielectric material layer to form a second opening, and depositing a second metal in the second opening to form the second metal wiring; and
depositing, at least one of:
prior to patterning the first dielectric material layer, a first dielectric cap on the first dielectric material layer, wherein forming the first opening further comprises patterning the first dielectric cap; and
prior to patterning the second dielectric material layer, a second dielectric cap on the second dielectric material layer, wherein forming the second opening further comprises patterning the second dielectric cap.
